(19) United States
(12) Patent Application Publication
(10) Pub. No.: US 2010/0117156 A1
(43) Pub. Date: May 13, 2010

(54) SEMICONDUCTOR DEVICE AND METHOD OF MANUFACTURING SEMICONDUCTOR DEVICE

(75) Inventors: Gen TSUTSUI, Kanagawa (JP); Kiyotaka IMAI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kawasaki-shi (JP)

(21) Appl. No.: 12/617,434

(22) Filed: Nov. 12, 2009

(30) Foreign Application Priority Data
Nov. 12, 2008 (JP) 2008-290403

(51) Int. Cl. H01L 27/088; H01L 21/8234

(52) U.S. Cl. 257/368; 438/197; 257/E27.06; 257/E21.616

(57) ABSTRACT

A semiconductor device includes a first transistor, a second transistor, a first interconnect, a second interconnect, and a first gate electrode. The first gate electrode is a gate electrode of the first and second transistors and extends linearly over first and second channel regions. In addition, a first source of the first transistor is located at the opposite side of a second source of the second transistor with the first gate electrode interposed therebetween, and a first drain of the first transistor is located at the opposite side of a second drain of the second transistor with the first gate electrode interposed therebetween.

This application is based on Japanese patent application NO. 2008-290403, the content of which is incorporated hereinto by reference.

### BACKGROUND

1. Technical Field

The present invention relates to a semiconductor device and a method of manufacturing a semiconductor device capable of suppressing a fluctuation in the on-state current of a transistor caused by misalignment of a gate electrode.

2. Related Art

The shape of a transistor in a semiconductor device has been studied in various ways, for example, as disclosed in Japanese Published patent application A-H03-278579, Japanese Unexamined patent publication NO. 2005-243928 and Non Patent Document “Mis-match Characterization of 1.8V and 3.3V Devices in 0.18 μm Mixed Signal CMOS Technology”, Ta-Hsun Yeh at el. (four persons), Proc. IEEE 2001 Int. Conference on Microelectronic Test Structure, Vol 14, March 2001.

Moreover, a transistor using a fin-shaped semiconductor layer, so-called Fin-FET (Field Effect Transistor) has been under development in recent years. For example, Japanese Unexamined patent publication NO. 2005-86024 discloses a transistor in which the width of a fin in the y direction changes in three steps assuming that a long side of the fin is the x direction and a short side of the fin is the y direction. In this transistor, the width of the fin in the y direction increases in the order of a channel region, source and drain extension regions, and source and drain regions. In addition, Japanese Unexamined patent publication NO. 2006-269975 discloses a transistor that has a plurality of fins arrayed in parallel over an insulating layer, gate electrodes provided at both side surfaces of a central portion of the fin with a gate insulating film interposed therebetween, and a semiconductor layer which connects fin portions located at both sides of the gate electrode to each other. Impurities are doped into the semiconductor layer and the fin portions located at both sides of the gate electrode to thereby form a source and drain layer.

When a gate electrode of a transistor is misaligned, either one of the source and drain regions becomes large and the other one becomes small. In this case, the parasitic resistance of the transistor changes, and the on-state current value of the transistor changes accordingly.

### SUMMARY

In one embodiment, there is provided a semiconductor device comprising: a first transistor including a first source, a first channel region, and a first drain; a second transistor including a second source, a second channel region, and a second drain; a first interconnect which is connected to the first source through a first plug and which is connected to the second source through a second plug; a second interconnect which is connected to the first drain through a third plug and which is connected to the second drain through a fourth plug; and a first gate electrode which is a gate electrode of the first and second transistors and extends linearly over the first and second channel regions. The first source is located at the opposite side of the second source with the first gate electrode interposed therebetween, and the first drain is located at the opposite side of the second drain with the first gate electrode interposed therebetween.

According to the embodiment of the present invention, the first gate electrode extends linearly over the first channel region of the first transistor and the second channel region of the second transistor. In addition, the first interconnect is connected to both the first and second sources, and the second interconnect is connected to both the first and second drains. For this reason, the first and second transistors are seemingly driven as one transistor. On the other hand, the first source of the first transistor is located at the opposite side of the second source of the second transistor with the first gate electrode interposed therebetween, and the first drain is located at the opposite side of the second drain with the first gate electrode interposed therebetween. For this reason, even if the first gate electrode is misaligned, the sum of the distance from the first plug of the first source to the first channel region and the distance from the second plug of the second source to the second channel region is not changed, and the sum of the distance from the third plug of the first drain to the first channel region and the distance from the fourth plug of the second drain to the second channel region is not changed. Accordingly, even if the first gate electrode is misaligned, a fluctuation in the parasitic resistance between the source and drain is suppressed. As a result, a fluctuation in the on-state current of the transistor is suppressed.

In another embodiment, there is provided a method of manufacturing a semiconductor device including: separating a first element forming region where a first transistor is formed from a second element forming region where a second transistor is formed; forming a gate electrode of the first transistor and a gate electrode of the second transistor in the first and second element forming regions as a first gate electrode with one linear shape; forming a first source and a first drain of the first transistor and a second source and a second drain of the second transistor by doping impurities into the first and second element forming regions using the first gate electrode as a mask; forming a first interconnect which is connected to the first source through a first plug and which is connected to the second source through a second plug; and forming a second interconnect which is connected to the first drain through a third plug and which is connected to the second drain through a fourth plug. In the step of forming the first and second interconnects, the first source is located at the opposite side of the second source with the first gate electrode interposed therebetween, and the first drain is located at the opposite side of the second drain with the first gate electrode interposed therebetween.

According to the embodiments of the present invention, it is possible to suppress a fluctuation in the on-state current of a transistor caused by misalignment of a gate electrode.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view showing the configuration of a semiconductor device according to a first embodiment;

FIG. 2 is a perspective view showing the semiconductor device shown in FIG. 1;

FIG. 3 is a sectional view taken along the line A-A′ of FIG. 1;

FIG. 4 is a sectional view taken along the line B-B′ of FIG. 1;

FIG. 5 is a sectional view taken along the line C-C′ of FIG. 1;

FIG. 6 is a plan view showing the case where a first gate electrode is misaligned;

FIG. 7 is a graph showing the simulation result of the effect of the first embodiment;

FIG. 8 is a plan view showing a semiconductor device according to a second embodiment;

FIG. 9 is a sectional view taken along the line A-A′ of FIG. 8;

FIG. 10 is a sectional view taken along the line B-B′ of FIG. 8;

FIG. 11 is a plan view showing a semiconductor device according to a third embodiment;

FIG. 12 is a plan view showing a semiconductor device according to a fourth embodiment;

FIG. 13 is a sectional view showing the details of a method of forming first and second gate electrodes;

FIG. 14 is a sectional view showing the details of a method of forming first and second gate electrodes; and

FIG. 15 is a sectional view showing the details of a method of forming first and second gate electrodes.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the present invention will be described with reference to the accompanying drawings. In addition, the same components are denoted by the same reference numerals in all drawings and these will not be repeated.

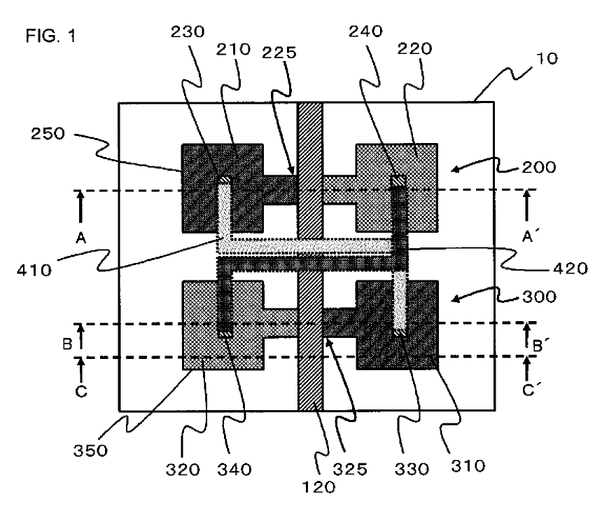

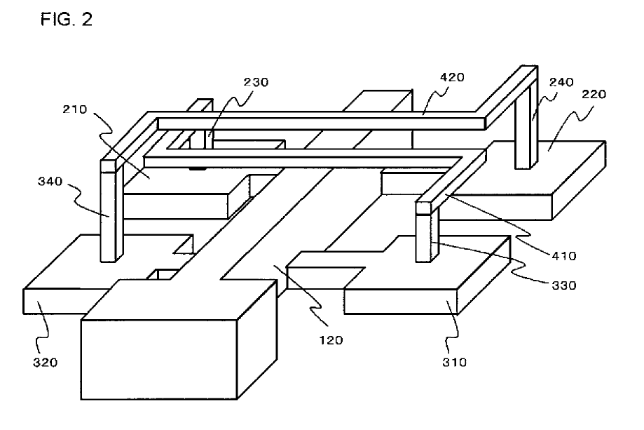

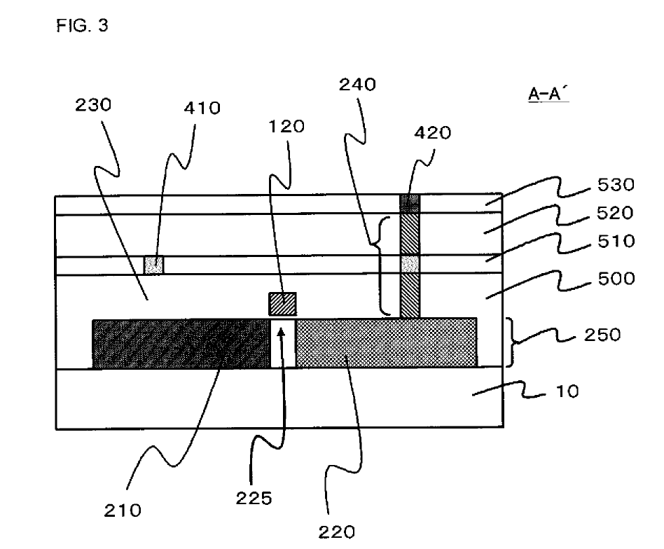

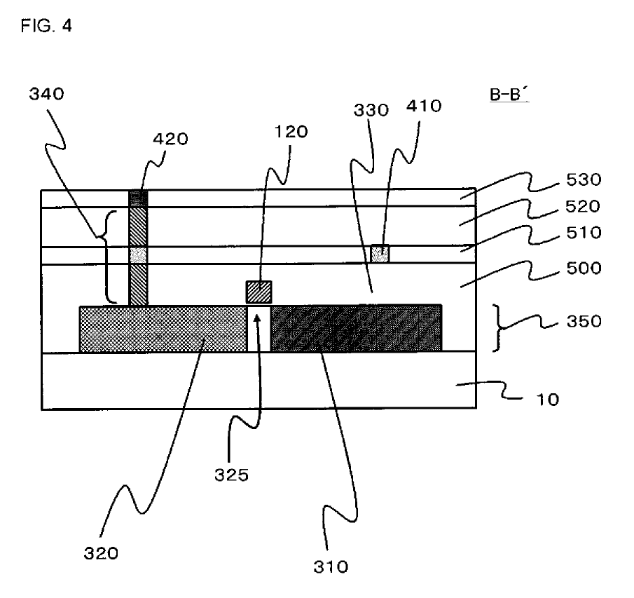

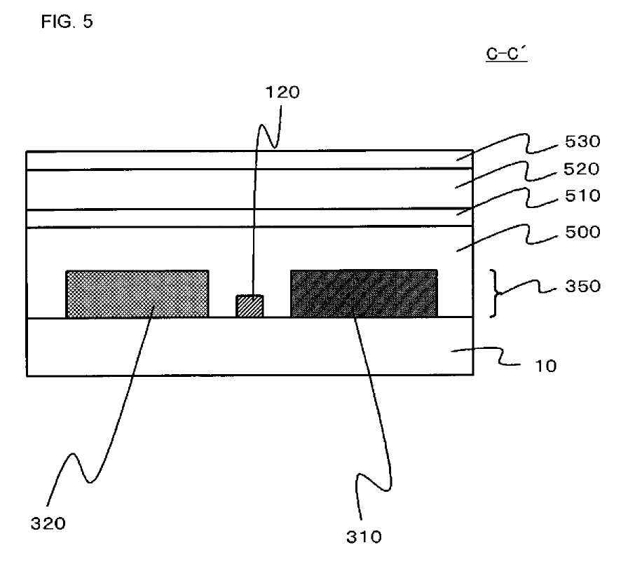

FIG. 1 is a plan view showing the configuration of a semiconductor device according to a first embodiment. FIG. 2 is a perspective view showing the semiconductor device shown in FIG. 1. FIG. 3 is a sectional view taken along the line A-A′ of FIG. 1. FIG. 4 is a sectional view taken along the line B-B′ of FIG. 1. FIG. 5 is a sectional view taken along the line C-C′ of FIG. 1. The semiconductor device includes a first transistor 200, a second transistor 300, a first interconnect 410, a second interconnect 420, and a first gate electrode 120. For example, the first and second transistors 200 and 300 are n-type transistors. However, the first and second transistors 200 and 300 may be p-type transistors.

The first transistor 200 has a first source 210, a first channel region 225, and a first drain 220. The second transistor 300 has a second source 310, a second channel region 325, and a second drain 320. The first interconnect 410 is connected to the first source 210 through a first plug 230 and is connected to the second source 310 through a second plug 330. The second interconnect 420 is connected to the first drain 220 through a third plug 240 and is connected to the second drain 320 through a fourth plug 340. The first gate electrode 120 is a gate electrode of the first and second transistors 200 and 300 and extends linearly over the first and second channel regions 225 and 325. In addition, the first source 210 is located at the opposite side of the second source 310 with the first gate electrode 120 interposed therebetween, and the first drain 220 is located at the opposite side of the second drain 320 with the first gate electrode 120 interposed therebetween.

In the first embodiment, the semiconductor device includes fin-shaped first and second semiconductor layers 250 and 350. The first source 210, first channel region 225, and first drain 220 of the first transistor 200 are formed in the first semiconductor layer 250. The second source 310, second channel region 325, and second drain 320 of the second transistor 300 are formed in the second semiconductor layer 350. In the first semiconductor layer 250, the neighborhood of a portion to which the first and third plugs 230 and 240 are connected is thicker than the other portions. In the second semiconductor layer 350, the neighborhood of a portion to which the second and fourth plugs 330 and 340 are connected is thicker than the other portions. That is, in the first semiconductor layer 250, the width is small in the first channel region 225 and its neighborhood, and the resistance values of the first source 210 and first drain 220 are large in the neighborhood of the first channel region 225. Moreover, in the second semiconductor layer 350, the width is small in the second channel region 325 and its neighborhood, and the resistance values of the second source 310 and second drain 320 are large in the neighborhood of the second channel region 325.

No element is formed between the first and second transistors 200 and 300. In addition, when seen in a plan view, the shape of the first transistor 200 is approximately the same as that of the second transistor 300. Each of the first and second transistors 200 and 300 has an axisymmetric shape with the first gate electrode 120 as a reference. In addition, the width of the first gate electrode 120 is equal to or less than 100 nm.

The first and second interconnects 410 and 420 are formed in different interconnect layers. In the first embodiment, the first interconnect 410 is formed in an interconnect layer immediately above the first gate electrode 120, and the second interconnect 420 is formed in an interconnect layer immediately above the first interconnect 410. Moreover, when seen in a plan view, both the first and second interconnects 410 and 420 overlap the first and second transistors 200 and 300 and the region interposed therebetween. In addition, in FIG. 1, the first and second interconnects 410 and 420 are thinner than the first gate electrode 120 in order to show the first plug 230 and the like. However, the first and second interconnects 410 and 420 may be thicker than the first gate electrode 120.

Next, a method of manufacturing the semiconductor device shown in FIGS. 1 to 5 will be described. First, a semiconductor layer is formed over a substrate 10 and the semiconductor layer is selectively removed. The substrate 10 is obtained by forming an insulating layer over a semiconductor substrate, for example. As a result, over the substrate 10, the first semiconductor layer 250 as a first element forming region and the second semiconductor layer 350 as a second element forming region are formed. The first semiconductor layer 250 and the second semiconductor layer 350 are separated from each other. Then, a gate insulating film (not shown in the drawings) is formed over the first and second semiconductor layers 250 and 350.

Then, a layer as a first gate electrode is formed over the gate insulating film and is selectively removed. As a result, the first gate electrode 120 is formed. The first gate electrode 120 may be a polysilicon gate electrode or may be a metal gate electrode. In addition, the method of forming the first gate electrode 120 is not limited to the above-described method.

Then, impurities are doped into the first and second semiconductor layers 250 and 350 by using the first gate electrode 120 as a mask. As a result, the first source 210 and first drain 220 of the first transistor and the second source 310 and second drain 320 of the second transistor are formed.

In addition, the extension regions of source and drain may be formed in the first and second semiconductor layers 250 and 350 before forming the first source 210, the first drain 220, the second source 310, and the second drain 320. In this case, after forming the extension regions, a sidewall may be formed at the sidewall of the first gate electrode 120 before forming the first source 210, the first drain 220, the second source 310, and the second drain 320.

Then, over the substrate 10, an insulating interlayer 500 is formed over the first semiconductor layer 250, the second semiconductor layer 350, and the first gate electrode 120. Then, an opening for embedding a plug in the insulating interlayer 500 is formed, and a plug is embedded in the opening. As a result, the first plug 230, the second plug 330, a part of the third plug 240, and a part of the fourth plug 340 are formed.

Then, an interconnecting insulating layer 510 is formed over the insulating interlayer 500. Then, a groove and an opening are formed in the interconnecting insulating layer 510, and a conductor (for example, copper) is embedded in the groove and the opening. As a result, the first interconnect 410, a part of the third plug 240, and a part of the fourth plug 340 are formed.

Then, an insulating interlayer 520 is formed over the interconnecting insulating layer 510, and a part of the third plug 240 and a part of the fourth plug 340 are embedded in the insulating interlayer 520. As a result, the remaining portions of the third and fourth plugs 240 and 340 are formed. Then, an interconnecting insulating layer 530 is formed over the insulating interlayer 520. Then, a groove is formed in the interconnecting insulating layer 530, and a conductor (for example, copper) is embedded in the groove. As a result, the second interconnect 420 is formed.

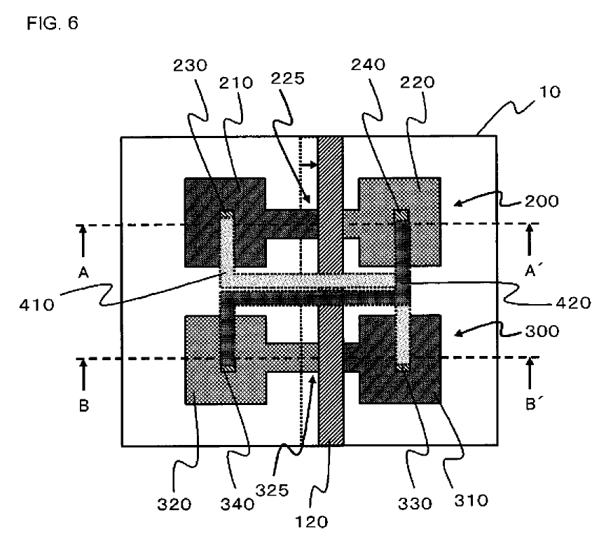

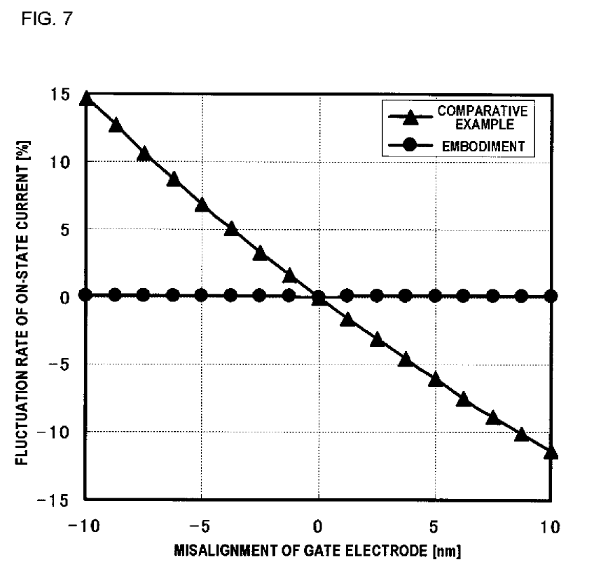

Next, operations and effects of the first embodiment will be described with reference to FIGS. 6 and 7. The first gate electrode 120 extends linearly over the first channel region 225 of the first transistor 200 and the second channel region 325 of the second transistor 300. In addition, the first interconnect 410 is connected to both the first source 210 of the first transistor 200 and the second source 310 of the second transistor 300, and the second interconnect 420 is connected to both the first drain 220 of the first transistor 200 and the second drain 320 of the second transistor 300. For this reason, the first and second transistors 200 and 300 are seemingly driven as one transistor.

FIG. 6 is a plan view showing the case where the first gate electrode 120 is misaligned. As described above, the first source 210 of the first transistor 200 is located at the opposite side of the second source 310 of the second transistor 300 with the first gate electrode 120 interposed therebetween, and the first drain 220 of the first transistor 200 is located at the opposite side of the second drain 320 with the first gate electrode 120 interposed therebetween. For this reason, even if the first gate electrode 120 is misaligned as shown in FIG. 6, the sum of the distance from the first plug 230 of the first source 210 to the first channel region 225 and the distance from the second plug 330 of the second source 310 to the second channel region 325 is not changed, and the sum of the distance from the third plug 240 of the first drain 220 to the first channel region 225 and the distance from the fourth plug 340 of the second drain 320 to the second channel region 325 is not changed. Accordingly, even if the first gate electrode 120 is misaligned, a fluctuation in the parasitic resistance between the source and drain is suppressed. As a result, a fluctuation in the on-state current of the transistor is suppressed.

FIG. 7 is a graph showing the simulation result of the effect of the first embodiment. In this graph, the horizontal axis indicates the amount (nm) of misalignment of the first gate electrode 120, and the vertical axis indicates the amount of on-state current of a transistor. In addition, the simulation was performed assuming that the first and second transistors 200 and 300 were n-type transistors. As a comparative example, the case where the first and second transistors 200 and 300 were independently driven was used. From this graph, it can be seen that the fluctuation in the on-state current of the transistor is suppressed in the first embodiment.

The above effect is especially noticeable when the shape of the first transistor 200 is approximately the same as that of the second transistor 300 when seen in a plan view. Moreover, when the width of the first gate electrode 120 becomes equal to or less than 100 nm due to miniaturization of the semiconductor device and when the first and second transistors 200 and 300 are formed in the fin-shaped first and second semiconductor layers 250 and 350, respectively, the effect becomes noticeable since the source and drain resistances of the transistor become large.

In addition, when a gate electrode is bent in the middle as disclosed in Japanese Published patent application A-H03-278579 and Japanese Unexamined patent publication NO. 2005-243928, the bent portion becomes round due to the optical proximity effect as the miniaturization of a transistor progresses. As a result, the characteristic of a transistor deteriorates. On the other hand, the first embodiment is resistant to influence by the optical proximity effect since the first gate electrode 120 has a linear shape. As a result, even if the miniaturization of a transistor progresses, the characteristics of a transistor are resistant to deterioration.

In addition, when the first transistor 200 is located next to the second transistor 300 and no element is formed between the first and second transistors 200 and 300, a fluctuation in the resistance among the first source 210, the first drain 220, the second source 310, and the second drain 320 can be suppressed. As a result, a fluctuation in the on-state current of a transistor can be further suppressed.

In addition, since the first and second interconnects 410 and 420 are formed in different interconnect layers, both the first and second interconnects 410 and 420 can be made to overlap the first and second transistors 200 and 300 and the region interposed therebetween when seen in a plan view. As a result, the semiconductor device can be made small.

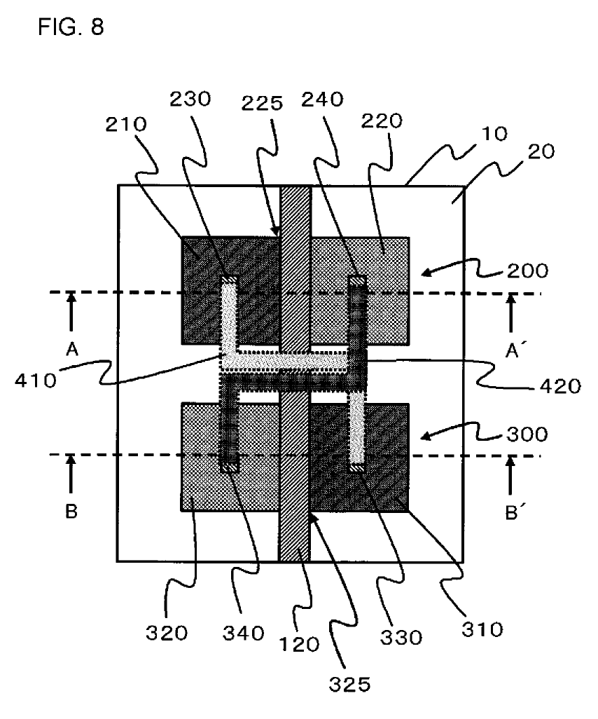

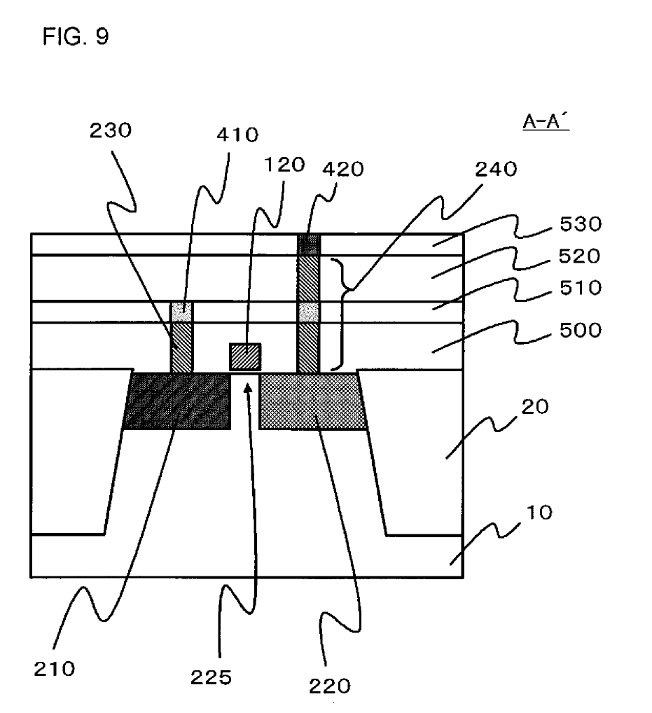

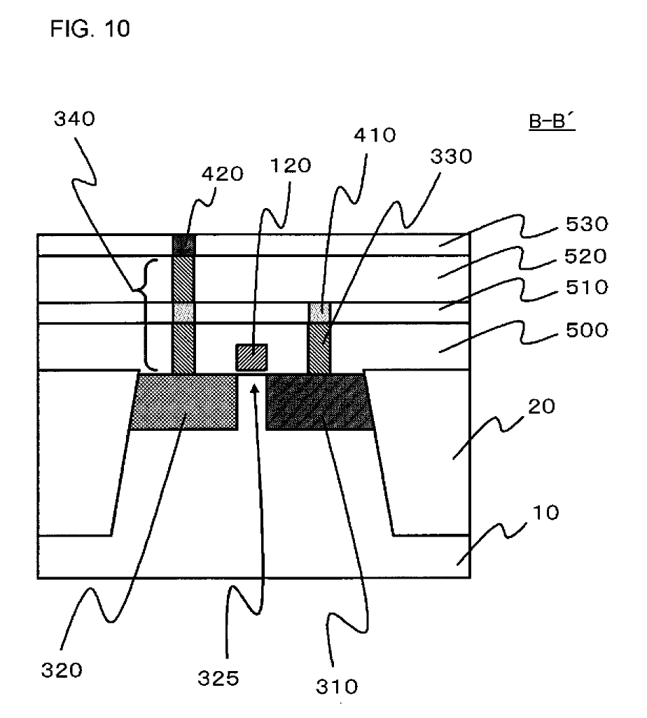

FIG. 8 is a plan view showing a semiconductor device according to a second embodiment. FIG. 9 is a sectional view taken along the line A-A′ of FIG. 8, and FIG. 10 is a sectional view taken along the line B-B′ of FIG. 8. The semiconductor device according to the second embodiment is the same as the semiconductor device according to the first embodiment except that first and second transistors 200 and 300 are formed in a substrate 10, which is a semiconductor substrate, and a first element forming region where the first transistor 200 is formed and a second element forming region where the second transistor 300 is formed are separated from each other by a element isolation film 20.

Also in the second embodiment, the same effect as in the first embodiment can be obtained.

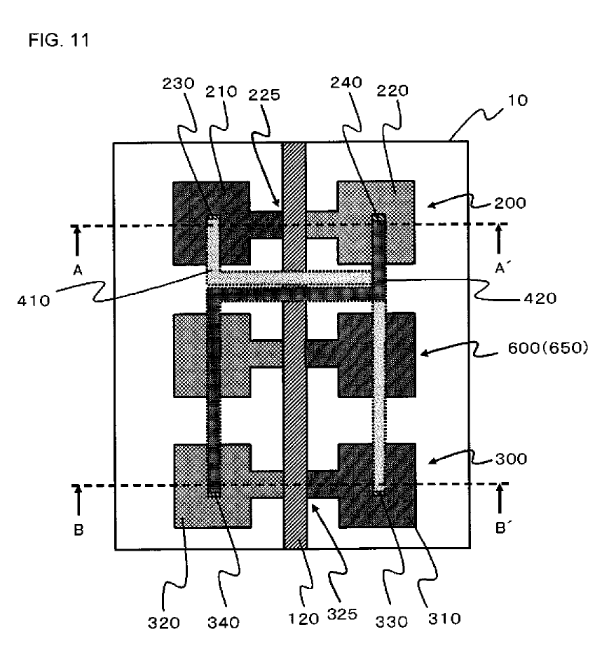

FIG. 11 is a plan view showing a semiconductor device according to a third embodiment. The semiconductor device has the same configuration as the first embodiment except that a third transistor 600 is formed between first and second transistors 200 and 300. The third transistor 600 is formed using a fin-shaped semiconductor layer 650, similar to the first and second transistors 200 and 300.

Also in the third embodiment, a fluctuation in the parasitic resistance between a source and a drain is suppressed by the same operation as in the first embodiment. As a result, a fluctuation in the on-state current of the transistor is suppressed. In the example shown in FIG. 11, the number of transistors is odd. However, the above-described effect is noticeable when the number of transistors is even.

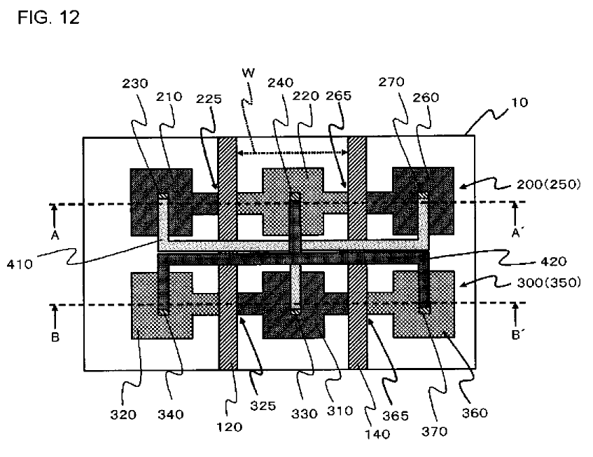

FIG. 12 is a plan view showing a semiconductor device according to a fourth embodiment. The semiconductor device has the same configuration as the semiconductor device according to the first embodiment except for the following points.

A first transistor 200 has a third channel region 265 and a third source 260. The third channel region 265 is located at the opposite side of a first channel region 225 with a first drain 220 interposed therebetween, and the third source 260 is located at the opposite side of the first drain 220 with the third channel region 265 interposed therebetween.

A second transistor 300 has a fourth channel region 365 and a third drain 360. The fourth channel region 365 is located at the opposite side of a second channel region 325 with a second source 310 interposed therebetween, and the third drain 360 is located at the opposite side of the second source 310 with the fourth channel region 365 interposed therebetween.

In addition, the first and second transistors 200 and 300 have a second gate electrode 140. The second gate electrode 140 extends linearly in a direction parallel to the first gate electrode 120 over the third and fourth channel regions 265 and 365. The distance W between the first and second gate electrodes 120 and 140 is equal to or less than 100 nm, for example.

In addition, a first interconnect 410 is connected to the third source 260 through a fifth plug 270, and a second interconnect 420 is connected to the third drain 360 through a sixth plug 370. The configuration of the fifth plug 270 is the same as that of the first plug 230, and the configuration of the sixth plug 370 is the same as that of the fourth plug 340.

A method of manufacturing the semiconductor device according to the fourth embodiment is the same as the method of manufacturing the semiconductor device applied to the first embodiment except for the following process of forming the first and second gate electrodes 120 and 140.

That is, the second gate electrode 140 is formed in the process of forming the first gate electrode 120. Moreover, in the process of forming the first source 210, the first drain 220, the second source 310, and the second drain 320, the third source 260 is formed in the first semiconductor layer 250 which is the first element forming region, and the third drain 360 is formed in the second semiconductor layer 350 which is the second element forming region. In addition, the fifth plug 270 is formed in the process of forming the first plug 230, and the sixth plug 370 is formed in the process of forming the fourth plug 340. In addition, the first interconnect 410 is connected to the third source 260 through the fifth plug 270 in the process of forming the first interconnect 410, and the second interconnect 420 is connected to the third drain 360 through the sixth plug 370 in the process of forming the second interconnect 420.

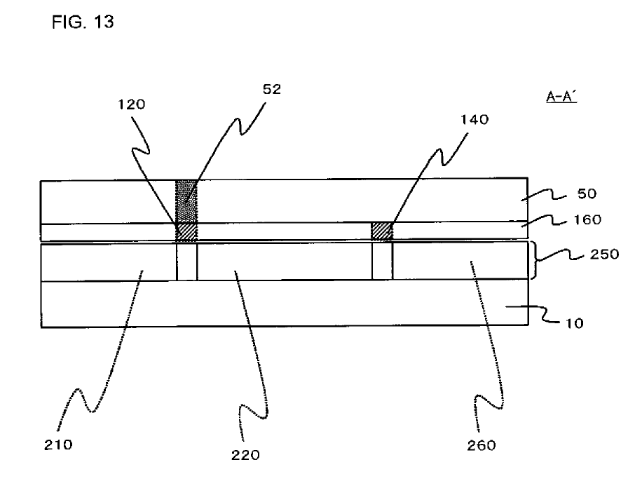

FIGS. 13, 14, and 15 are sectional views showing the details of the method of forming the first and second gate electrodes 120 and 140 in the fourth embodiment and correspond to the sectional views taken along the lines A-A′ of FIG. 12, respectively. In the fourth embodiment, the first and second gate electrodes 120 and 140 are formed using double patterning. That is, the process of forming the first and second gate electrodes 120 and 140 includes a first exposure process of forming the first gate electrode 120 and a second exposure process of forming the second gate electrode 140.

First, as shown in FIG. 13, a layer 160 that becomes the first and second gate electrodes 120 and 140 is formed, and a resist film 50 is then formed over the layer 160. The resist film 50 is of a negative type, for example. Then, the first exposure is performed on the resist film 50 using a first reticule (not shown) such that a first mask region 52 of the resist film 50, which is located over the region that becomes the first gate electrode 120, is changed in quality.

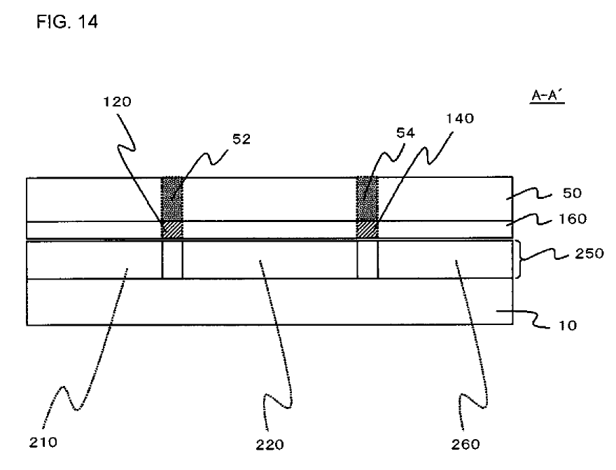

Then, as shown in FIG. 14, the second exposure is performed on the resist film 50 using a second reticule (not shown) such that a second mask region 54 of the resist film 50, which is located over the region that becomes the second gate electrode 140, is changed in quality.

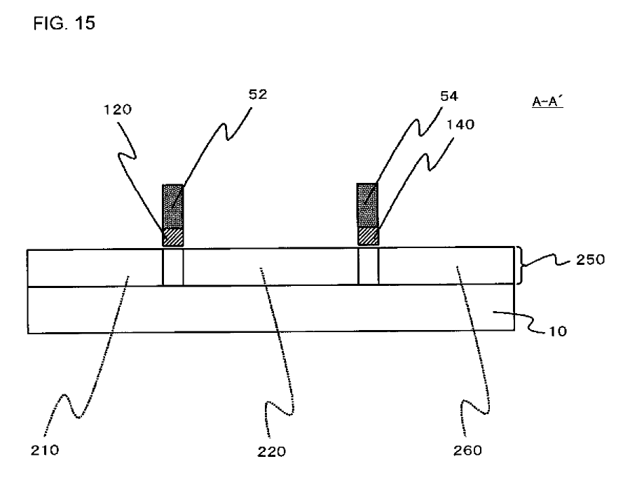

Then, as shown in FIG. 15, the resist film 50 is developed. As a result, the resist film 50 is removed except for the first and second mask regions 52 and 54. Then, the layer 160 is etched using the first and second mask regions 52 and 54 of the resist film 50 as a mask. As a result, the layer 160 is selectively removed, such that the first and second gate electrodes 120 and 140 are formed. Then, the first and second mask regions 52 and 54 of the resist film 50 are removed.

Also in the fourth embodiment, the same effect as in the first embodiment can be obtained. In addition, since the first and second gate electrodes 120 and 140 have linear shapes and are parallel to each other, double patterning can be used when forming the first and second gate electrodes 120 and 140. Therefore, the distance between the first and second gate electrodes 120 and 140 can be made to be narrow (for example, equal to or less than 100 nm) by miniaturizing the transistor.

In addition, double patterning is not limited to the above-described method. For example, the first and second gate electrodes 120 and 140 may be formed by performing exposure, development, and etching twice. In addition, a positive resist may be used as the resist film 50.

Having described the above embodiments of the present invention with reference to the accompanying drawings, these are illustrative of the present invention, and various configurations other than those described above may also be adopted.

It is apparent that the present invention is not limited to the above embodiment, but may be modified and changed without departing from the scope and spirit of the invention.

What is claimed is:

1. A semiconductor device comprising:
a first transistor including a first source, a first channel region, and a first drain;
a second transistor including a second source, a second channel region, and a second drain;
a first interconnect which is connected to said first source through a first plug and which is connected to said second source through a second plug;
a second interconnect which is connected to said first drain through a third plug and which is connected to said second drain through a fourth plug; and
a first gate electrode which is a gate electrode of said first and second transistors and extends linearly over said first and second channel regions,
wherein said first source is located at the opposite side of said second source with said first gate electrode interposed between said first and second sources, and said first drain is located at the opposite side of said second drain with said first gate electrode interposed between said first and second drains.

2. The semiconductor device according to claim 1,
wherein no element is formed between said first and second transistors.

3. The semiconductor device according to claim 1,
wherein the shape of said first transistor is approximately the same as that of said second transistor when seen in a plan view.

4. The semiconductor device according to claim 1,
wherein said first and second interconnects are formed in different interconnect layers.

5. The semiconductor device according to claim 1,
wherein the width of said first gate electrode is equal to or less than 100 nm.

6. The semiconductor device according to claim 1,
wherein said first transistor includes a third channel region, which is located at the opposite side of said first channel region with said first drain interposed between said first and third channel regions, and a third source, which is located at the opposite side of said first drain with said third channel region interposed between said third source and said first drain,
said second transistor includes a fourth channel region, which is located at the opposite side of said second channel region with said second source interposed between said second and fourth channel regions, and a third drain, which is located at the opposite side of said second source with said fourth channel region interposed between said third drain and said second source,
a second gate electrode of said first and second transistors, which extends linearly in a direction parallel to said first gate electrode over said third and fourth channel regions, is further provided, and
said first interconnect is connected to said third source through a fifth plug, and
said second interconnect is connected to said third drain through a sixth plug.

7. The semiconductor device according to claim 6,
wherein a distance between said first and second gate electrodes is equal to or less than 100 nm.

8. The semiconductor device according to claim 1, further comprising:
fin-shaped first and second semiconductor layers,
wherein said first source, said first channel region, and said first drain of said first transistor are formed in said first semiconductor layer, and
said second source, said second channel region, and said second drain of said second transistor are formed in said second semiconductor layer.

9. A method of manufacturing a semiconductor device, comprising:
separating a first element forming region where a first transistor is formed from a second element forming region where a second transistor is formed;
forming a gate electrode of said first transistor and a gate electrode of said second transistor in said first and second element forming regions as a first gate electrode with one linear shape;
forming a first source and a first drain of said first transistor and a second source and a second drain of said second transistor by doping impurities into said first and second element forming regions using said first gate electrode as a mask;
forming a first interconnect which is connected to said first source through a first plug and which is connected to said second source through a second plug; and
forming a second interconnect which is connected to said first drain through a third plug and which is connected to said second drain through a fourth plug,
wherein in said step of forming said first and second interconnects, said first source is located at the opposite side of said second source with said first gate electrode interposed between said first and second sources, and said first drain is located at the opposite side of said second drain with said first gate electrode interposed between said first and second drains.

10. The method according to claim 9,
wherein in said step of forming said first gate electrode, a second gate electrode extending in parallel to said first gate electrode is formed in said first and second element forming regions,
in said step of forming said first source, said first drain, said second source, and said second drain, a third source which is located at the opposite side of said first drain with said second gate electrode interposed between said third source and said first drain is formed in said first element forming region, and a third drain which is located at the opposite side of said second source with said second gate electrode interposed between said third drain and said second source is formed in said second element forming region,
in said step of forming said first interconnect, said first interconnect is connected to said third source through a fifth plug,
in said step of forming said second interconnect, said second interconnect is connected to said third drain through a sixth plug, and
said step of forming said first and second gate electrodes includes performing first exposure for forming said first gate electrode and performing second exposure for forming said second gate electrode.
